(19) United States
(12) Patent Application Publication
(10) Pub. No.: US 2024/0110844 A1
(43) Pub. Date: Apr. 4, 2024

(54) EXPOSURE APPARATUS AND INSPECTION METHOD

(71) Applicant: NIKON CORPORATION, Tokyo (JP)

(72) Inventors: Masaki KATO, Yokohama-shi (JP); Hitoshi MIZUNO, Yokohama-shi (JP); Yasushi MIZUNO, Saitama-shi (JP)

(73) Assignee: NIKON CORPORATION, Tokyo (JP)

(21) Appl. No.: 18/528,108

(22) Filed: Dec. 4, 2023

Related U.S. Application Data
(63) Continuation of application No. PCT/JP2022/025555, filed on Jun. 27, 2022.

(30) Foreign Application Priority Data
Jul. 5, 2021 (JP) 2021-111677

(51) Int. Cl. G01M 11/02; G03F 7/00

(52) U.S. Cl. CPC G01M 11/0264; G03F 7/7065; G03F 7/706849

(57) ABSTRACT

An exposure apparatus exposes an object to pattern light generated by a spatial light modulator having a plurality of elements in accordance with drawing data. The exposure apparatus includes a data output unit configured to output the drawing data to the spatial light modulator, an illumination optical system configured to irradiate the spatial light modulator with illumination light, a first movable body configured to hold the object, a projection optical system configured to project an image of the pattern light generated by the spatial light modulator onto the object, a detection unit configured to detect the image of the pattern light that has been projected, and a determination unit configured to determine whether the spatial light modulator is capable of generating pattern light in accordance with the drawing data output from the data output unit, based on a detection result of the detection unit.

### CROSS-REFERENCE TO RELATED APPLICATION

This application is based upon and claims the benefit of priority of the prior International Patent Application No. PCT/JP2022/025555, filed on Jun. 27, 2022, the entire contents of which are incorporated herein by reference.

### FIELD

The present disclosure relates to an exposure apparatus and an inspection method.

### BACKGROUND

Conventionally, in a lithography process for manufacturing electronic devices (microdevices) such as display panels using liquid crystal or organic EL, or semiconductor devices (integrated circuits, or the like), a step-and-repeat projection exposure apparatus (so-called a stepper), a step-and-scan projection exposure apparatus (so-called a scanning stepper (also called a scanner)) or the like is used. This type of exposure apparatus projects and exposes a mask pattern for an electronic device onto a photosensitive layer applied on the surface of a substrate to be exposed (hereinafter, also simply referred to as a substrate) such as a glass substrate, a semiconductor wafer, a printed wiring board, or a resin film.

It takes time and cost to manufacture a mask substrate on which the mask pattern is fixedly formed. Therefore, there is known an exposure apparatus using a spatial light modulation element (variable mask pattern generator) such as a digital mirror device (DMD) in which a large number of micromirrors that are slightly displaced are regularly arranged instead of the mask substrate (for example, see Patent Document 1: Japanese Patent Application Laid-Open No. 2019-23748). The exposure apparatus disclosed in Patent Document 1 irradiates the digital mirror device (DMD) with illumination light obtained by mixing light from a laser diode (LD) with a wavelength of 375 nm and light from another LD with a wavelength of 405 nm by a multi-mode fiber bundle, and projects and exposes light reflected from each of a large number of tilt-controlled micromirrors onto the substrate via an imaging optical system and a microlens array.

If a defective element is generated in the DMD, a desired pattern may not be projected and exposed onto the substrate. Therefore, it is desired to identify the DMD including the defective element.

### SUMMARY

In a first aspect of the present disclosure, there is provided an exposure apparatus that exposes an object to pattern light in accordance with drawing data generated by a spatial light modulator having a plurality of elements, the exposure apparatus including: a data output unit configured to output the drawing data to the spatial light modulator; an illumination optical system configured to irradiate the spatial light modulator with illumination light; a first movable body configured to hold the object; a projection optical system configured to project an image of the pattern light generated by the spatial light modulator onto the object; a detection unit configured to detect the image of the pattern light that has been projected; and a determination unit configured to determine whether the spatial light modulator is capable of generating pattern light in accordance with the drawing data output from the data output unit, based on a detection result of the detection unit.

In a second aspect of the present disclosure, there is provided an inspection method for inspecting a spatial light modulator of an exposure apparatus. The exposure apparatus including the spatial light modulator configured to have a plurality of elements that generate pattern light in accordance with drawing data, an illumination optical system configured to irradiate the spatial light modulator with illumination light, and a projection optical system configured to project an image of the pattern light generated by the spatial light modulator onto an object placed on a first movable body. The inspection method includes: detecting the image of the pattern light that has been projected; and determining whether the spatial light modulator has a defective element not capable of being driven in accordance with the drawing data, based on a detection result of the image of the pattern light.

In a third aspect of the present disclosure, there is provided an inspection method for inspecting a spatial light modulator of an exposure apparatus. The exposure apparatus includes the spatial light modulator configured to have a plurality of elements that generate pattern light in accordance with drawing data, an illumination optical system configured to irradiate the spatial light modulator with illumination light, and a projection optical system configured to project an image of the pattern light generated by the spatial light modulator onto an object placed on a first movable body. The inspection method includes: exposing the image to the object; and determining whether the spatial light modulator has a defective element not capable of being driven in accordance with the drawing data by measuring the object to which the image is exposed using a measuring device.

In a fourth aspect of the present disclosure, there is provided an inspection method for inspecting a spatial light modulator of an exposure apparatus. The exposure apparatus including the spatial light modulator configured to have a plurality of elements that generate pattern light in accordance with drawing data, an illumination optical system configured to irradiate the spatial light modulator with illumination li and a projection optical system configured to project an image of the pattern light generated by the spatial light modulator onto an object placed on a first movable body. The inspection method includes: exposing the image of the patterned light generated by the spatial light modulator to a photochromic element; and determining whether the spatial light modulator has a defective element not capable of being driven in accordance with the drawing data by measuring the photochromic element to which the image of the pattern light is exposed by using a measuring device.

In a fifth aspect of the present disclosure, there is provided an exposure apparatus that exposes an object to pattern light in accordance with drawing data generated by a spatial light modulator having a plurality of elements. The exposure apparatus includes: an illumination optical system configured to irradiate the spatial light modulator with illumination light; a first movable body configured to hold the object; a projection optical system configured to project an image of the pattern light generated by the spatial light modulator onto the object; and a measurement unit configured to obtain a measurement result of the image of the pattern light on the object; wherein the measurement unit determines whether the spatial light modulator has a defective element not capable of being driven in accordance with the drawing data, based on the measurement result.

In a sixth aspect of the present disclosure, there is provided an exposure apparatus that exposes an object to pattern light in accordance with drawing data generated by a spatial light modulator having a plurality of elements. The exposure apparatus including: an illumination optical system configured to irradiate the spatial light modulator with illumination light; a first movable body configured to hold a photochromic element; a projection optical system configured to project an image of the pattern light generated by the spatial light modulator onto the photochromic element; and a measurement unit configured to obtain a measurement result of the photochromic element on which the image of the pattern light is projected; wherein the measurement unit determines whether the spatial light modulator has a defective element not capable of being driven in accordance with the drawing data, based on the measurement result.

Note that the configurations of the embodiments described below may be appropriately improved, and at least a part of the configurations may be replaced with another configuration. Furthermore, constituent elements whose arrangement is not particularly limited are not limited to the arrangement disclosed in the embodiments, and can be arranged at positions where their functions can be achieved.

### BRIEF DESCRIPTION OF DRAWINGS

FIG. 1 is a perspective view illustrating an outline of an external configuration of an exposure apparatus according to an embodiment;

FIG. 2 illustrates an arrangement example of projection regions of DMDs projected onto a substrate by respective projection units of a plurality of exposure modules;

FIG. 3 is a diagram for describing a state of joint exposure by each of four specific projection regions in FIG. 2;

FIG. 4 is an optical arrangement diagram of a specific configuration of two exposure modules arranged in an X-axis direction (scanning exposure direction), as viewed in an XZ plane;

FIG. 5A schematically illustrates the DMD, FIG. 5B illustrates the DMD when a power is off, FIG. 5C is a view for describing a mirror in an ON state, and FIG. 5D is a view for describing the mirror in an OFF state;

FIG. 6 schematically illustrates a state in which the DMD and an illumination unit are tilted by an angle θk in the XY plane;

FIG. 7 is a diagram for describing in detail an imaging state of micromirrors in the DMD by a projection unit;

FIG. 8 illustrates a schematic configuration of an alignment device provided in a calibration reference unit attached to an end portion of a substrate holder of the exposure apparatus;

FIG. 9 illustrates the substrate holder as viewed from a +Z direction;

FIG. 10A illustrates a schematic configuration of an inspection device that includes an enlargement imaging system and is provided in an inspection unit provided. at the end portion of the substrate holder, and FIG. 10B illustrates a schematic configuration of an inspection device that does not include the enlargement imaging system and is provided in the inspection unit provided at the end portion of the substrate holder;

FIG. 11 is a functional block diagram of an inspection control device provided in the exposure apparatus;

FIG. 12 is a flowchart illustrating an example of processes executed by the inspection control device;

FIG. 13 is a flowchart illustrating the details of an inspection process;

FIG. 14A illustrates an image of a first inspection pattern projected on an imaging device when the DMD has no defective element, FIG. 14B illustrates an image of the first inspection pattern projected on one pixel of the imaging device surrounded by a dotted line in FIG. 14A, FIG. 14C illustrates an image of a second inspection pattern projected on the imaging device when the DMD has no defective element, and FIG. 14D illustrates an image of the second inspection pattern projected on one pixel of the imaging device surrounded by a dotted line in FIG. 14C;

FIG. 15A illustrates a plurality of elements included in regions of the DMD corresponding to one pixel of the imaging device, and FIG. 15B is a diagram for describing a case where the plurality of elements in the DMD are divided into a plurality of blocks;

FIG. 16 illustrates the plurality of elements in the DMD corresponding to one pixel of the imaging device; and

FIG. 17A illustrates a first variation of images of the first inspection pattern and the second inspection pattern projected on the imaging device when the DMD has no defective element, and FIG. 17B illustrates a second variation of images of the first inspection pattern and the second inspection pattern projected on the imaging device when the DMD has no detective element.

### DESCRIPTION OF EMBODIMENTS

A pattern exposure apparatus (hereinafter, simply referred to as an exposure apparatus) according to an embodiment will be described with reference to the drawings.

### [Overall Configuration of Exposure Apparatus]

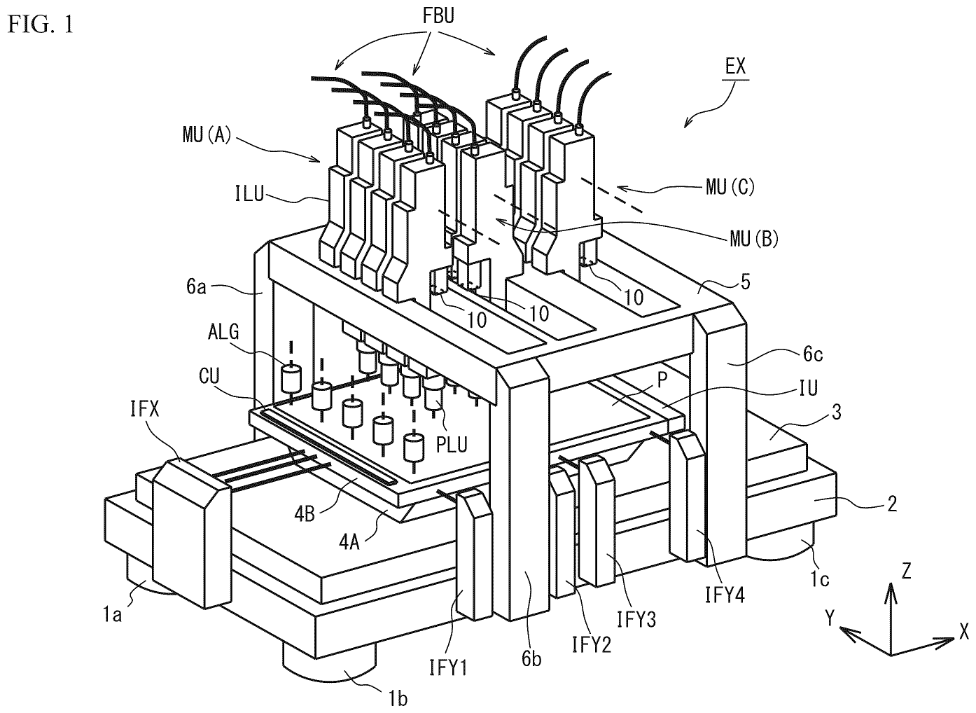

FIG. 1 is a perspective view illustrating an outline of an external configuration of an exposure apparatus EX according to an embodiment. The exposure apparatus EX is an apparatus that images and projects exposure light, whose intensity distribution in a space is dynamically modulated by a spatial light modulator (SLM), onto a substrate to be exposed. Examples of the spatial light modulator include a liquid crystal element, a digital micromirror device (DMD), and a magneto optic spatial light modulator (MOSLM). The exposure apparatus EX according to the present embodiment is provided with a DMD 10 as the spatial light modulator, but may be provided with another spatial light modulator.

In a specific embodiment, the exposure apparatus EX is a step-and-scan projection exposure apparatus (scanner) that uses a rectangular (square) glass substrate used for a display device (flat panel display) or the like as an exposure object. The glass substrate is a substrate P for a flat panel display that has at least one side length or a diagonal length of 500 mm or greater and a thickness of 1 mm or less. The exposure apparatus EX exposes a projected image of a pattern formed by the DMD onto a photosensitive layer (a photoresist) with a constant thickness formed on the surface of the substrate P. The substrate P carried out from the exposure apparatus EX after the exposure is sent to a predetermined process step (a film forming step, an etching step, a plating step, or the like) after a developing step.

The exposure apparatus EX includes a stage apparatus having a pedestal 2 placed on active vibration isolation units 1a, 1b, 1c, 1d (1d is not illustrated), a surface plate 3 placed on the pedestal 2, an XY stage 4A (a first driving unit) two dimensionally movable on the surface plate 3, a substrate holder 4B (a first movable body) that holds a substrate P (an object) on the XY stage 4A by suction, and laser length measuring interferometers (hereinafter, simply referred to as interferometers) IFX, IFY1 to IFY4 that measure two-dimensional movement positions of the substrate holder 4B (the substrate P). Such a stage device is disclosed, for example, in U.S. Patent Publication No. 2010/0018950 and U.S. Patent Publication No. 2012/0057140.

In FIG. 1, an XY plane of an orthogonal coordinate system XYZ is set parallel to a flat surface of the surface plate 3 of the stage apparatus, and the XY stage 4A is set so as to be translationally movable in the XY plane. In the present embodiment, a direction parallel to an X-axis of the coordinate system XYZ is set as a scanning movement direction of the substrate P (the XY stage 4A) during scanning exposure. A movement position of the substrate P in an X-axis direction is sequentially measured by the interferometer IFX, and a movement position of the substrate P in a Y-axis direction is sequentially measured by at least one or more (preferably two or more) of the four interferometers IFY1 to IFY4. The substrate holder 4B is configured to be slightly movable in a Z-axis direction perpendicular to the XY plane with respect to the XY stage 4A and to be slightly tiltable in any direction with respect to the XY plane, and focus adjustment and leveling (parallelism) adjustment between the surface of the substrate P and the imaging plane of the projected pattern are actively performed. Furthermore, the substrate holder 4B is configured to be slightly rotatable (θz rotation) around an axial line parallel to a Z-axis in order to actively adjust the tilt of the substrate P in the XY plane.

The exposure apparatus EX further includes an optical surface plate 5 that holds a plurality of exposure (drawing) module groups MU(A), MU(B), and MC(C), and main columns 6a, 6b, 6c, and 6d (6d is not illustrated) that support the optical surface plate 5 from the pedestal 2. Each of the exposure module groups MU(A), MU(B), and MU(C) are mounted at the +Z direction side of the optical surface plate 5. Each of the exposure module groups MU(A), MU(B), and MU(C) has an illumination unit ILU, which is attached to the +Z direction side of the optical surface plate 5 and allows illumination light to enter from an optical fiber unit FBU, and a projection unit PLU, which is attached to the −Z direction side of the optical surface plate 5 and has an optical axis parallel to the Z-axis. Furthermore, each of the exposure module groups MU(A), MU(B), and MU(C) has the DMD 10 as an optical modulator that reflects illumination light from the illumination unit ILU toward the −Z direction to cause the illumination light to enter the projection unit PLU. The detailed configuration of the exposure module with the illumination unit the ILU 10, and the projection unit PLU is described later.

A plurality of alignment systems (microscopes) ALG that detect alignment marks formed at a plurality of predetermined positions on the substrate P are attached to the −Z direction side of the optical surface plate 5 of the exposure apparatus EX. A calibration reference unit CU is provided at the end portion of the substrate holder 4B in the −X direction, to check (calibrate) a relative positional relationship of the detection fields of the alignment systems ALG in the XY plane, check (calibrate) baseline errors between the projected positions of the pattern images projected from respective projection units PLU of the exposure module groups MU(A), MU(B) and MU(C) and the positions of the detection fields of the alignment systems ALG, or check the positions and the image qualities of the pattern images projected from the projection units PLU. Although some of modules of the exposure module groups MU(A), MU(B), and MU(C) are not illustrated in FIG. 1, in the present embodiment, nine modules are arranged at a constant interval in the Y-axis direction in each of the exposure module groups MU(A), MU(B), and MU(C) as an example, but the number of modules may be less than nine or more than nine. Further, in FIG. 1, the exposure modules are arranged in three rows in the X-axis direction, but the number of rows of the exposure modules arranged in the X-axis direction may be two or less, or may be four or more.

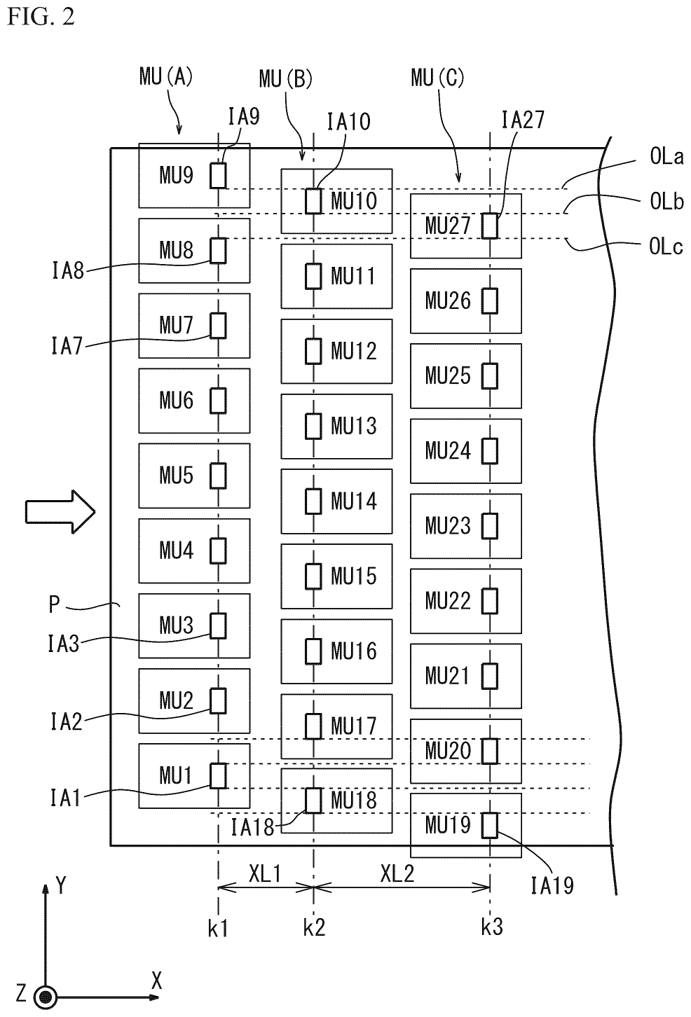

FIG. 2 illustrates an arrangement example of projection regions IAn of the DMDs 10 projected onto the substrate P by respective projection units PLU of the exposure module groups MU(A), MU(B), and MU(C). The orthogonal coordinate system XYZ is set to be the same as in FIG. 1. In the present embodiment, the exposure module group MU(A) in the first column, the exposure module group MU(B) in the second column, and the exposure module group MU(C) in the third column are arranged separately in the X-axis direction, and each of the exposure module groups MU(A), MU(B), and MU(C) includes nine modules arranged in the Y-axis direction. The exposure module group MU(A) includes nine modules MU1 to MU9 arranged in the +Y direction, the exposure module group MU(B) includes nine modules MU10 to MU18 arranged in the −Y direction, and the exposure module group MU(C) includes nine modules MU19 to MU27 arranged in the +Y direction. The modules MU1 to MU27 all have the same configuration. When the exposure module groups MU(A) and MU(B) are in a face-to-face relationship with respect to the X-axis direction, the exposure module groups MU(B) and MU(C) are in a back-to-back relationship with respect to the X-axis direction.

In FIG. 2, the shapes of projection regions IA1, IA2, IA3, . . . , IA27 (which may be denoted by IAn where n is 1 to 27) by the modules MU1 to MU27 are, for example, rectangles extending in the Y-axis direction with an aspect ratio of approximately 1:2. In the present embodiment, the joint exposure is performed at the end in the −Y direction of each of the projection regions IA1 to IA9 in the first column and the end in the +Y direction of each of the projection regions IA10 to IA18 in the second column, in accordance with the scanning movement of the substrate P in the +X direction. Then, regions on substrate P that have not been exposed by the projection regions IA1 to IA18 in the first and second columns are subjected to the joint exposure by the projection regions IA19 to IA27 in the third column, respectively. Center points of the projection regions IA1 to IA .9 in the first column are located on a line k1 parallel to the Y-axis, center points of the projection regions IA10 to 1A18 in the second column are located on a line k2 parallel to the Y-axis, and center points of the projection regions IA19 to IA27 in the third column are located on a line k3 parallel to the Y-axis. An interval between the lines k1 and k2 in the X-axis direction is set to be a distance XL1, and an interval between the lines k2 and k3 in the X-axis direction is set to be a distance XL2.

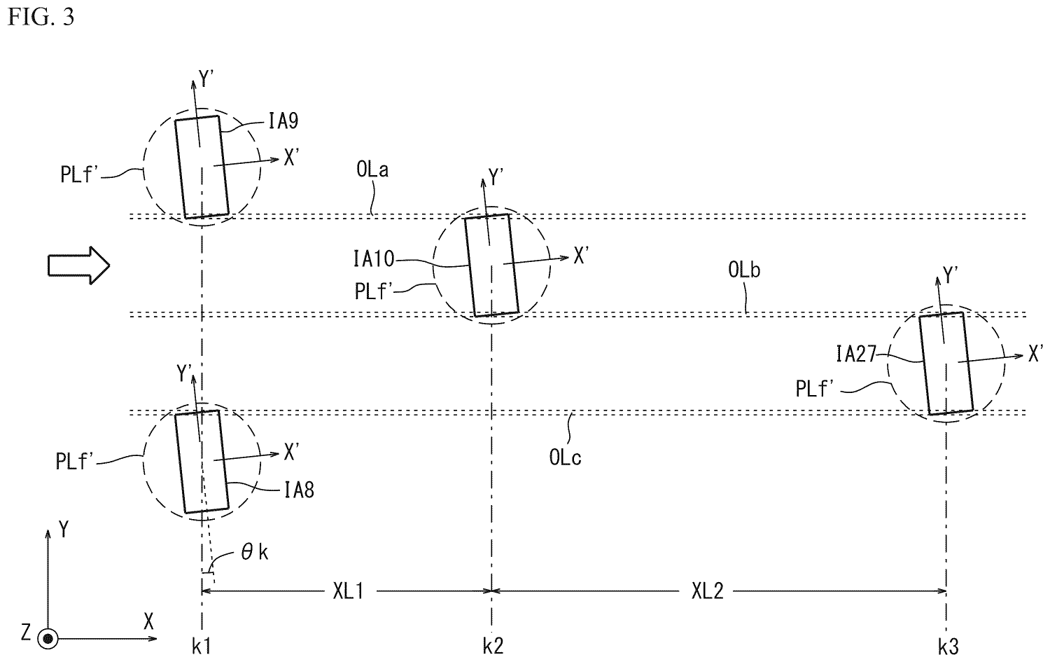

Here, the state of the joint exposure will be described with reference to FIG. 3, where OLa is a joint portion between the end of the projection region IA9 in the −Y direction and the end of the projection region IA10 in the +Y direction, OLb is a joint portion between the end of the projection region IA10 in the −Y direction and the end of the projection region IA27 in the +Y direction, and OLc is a joint portion between the end of the projection region IA8 in the +Y direction and the end of the projection region IA27 in the −Y direction. In FIG. 3, the orthogonal coordinate system XYZ is set to be the same as in FIG. 1 and FIG. 2, and a coordinate system X′Y′ in the projection regions IA8, IA9, IA10, and IA27 (and all other projection regions IAn) is set so as to be tilted by an angle θk with respect to the X-axis and the Y-axis (lines k1 to k3) of the orthogonal coordinate system XYZ. That is, the entire DMD 10 is tilted by the angle θk in the XY plane so that the two-dimensional array of the large number of micromirrors in the DMD 10 is the coordinate system X′Y′.

A circular region encompassing each of the projection regions IA8, IA9, IA10, IA27 (and all other projection regions IAn as well) in FIG. 3 represents a circular image field PLf′ of the projection unit PLU. In the joint portion OLa, the projected images of the micromirrors arranged obliquely (at the angle θk) at the end of the projection region IA9 in the −Y′ direction and the projected images of the micromirrors arranged obliquely (at the angle θk) at the end of the projected region IA10 in the +Y′ direction are set to overlap each other. In the joint portion OLb, the projected images of the micromirrors arranged obliquely (at the angle θk) at the end of the projection region IA10 in the −Y′ direction and the projected images of the micromirrors arranged obliquely (at the angle θk) at the end of the projected region IA27 in the +Y′ direction are set to overlap each other. Similarly, in the joint portion OLc, the projected images of the micromirrors arranged obliquely (at the angle θk) at the end of the projection region IA8 in the +Y′ direction and the projected images of the micromirrors arranged obliquely (at the angle θk) at the end of the projection region IA27 in the −Y′ direction are set to overlap each other.

### [Configuration of Illumination Unit]

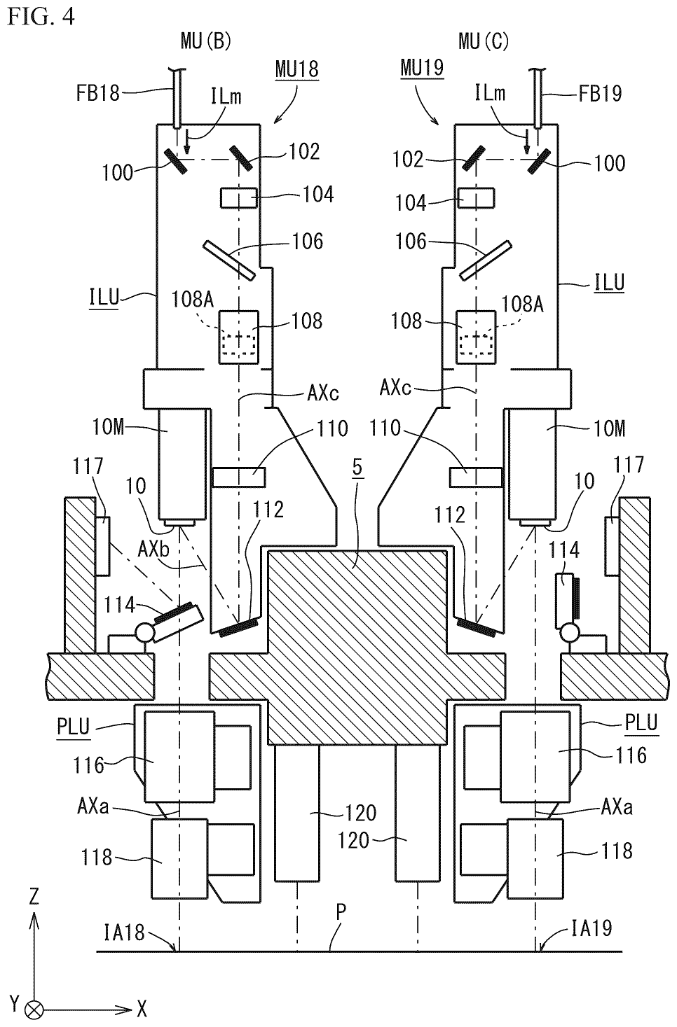

FIG. 4 is an optical arrangement diagram illustrating the specific configuration of the module MU18 in the exposure module group MU(B) and the module MU19 in the exposure module group MU(C) illustrated in FIG. 1 and FIG. 2, as viewed in the XZ plane. The orthogonal coordinate system XYZ in FIG. 4 is set to be the same as the orthogonal coordinate system XYZ in FIG. 1 to FIG. 3. As is clear from the arrangement of the modules in the XY plane illustrated in FIG. 2, the module MU18 is shifted by the predetermined interval in the +Y direction with respect to the module MU19, and the modules MU18 and MU19 are arranged in the back-to-back relationship. Since each optical member in the module MU18 and each optical member in the module MU19 are made of the same material and have the same configuration, the optical configuration of the module MU18 will be mainly described in detail here. The optical fiber unit FBU illustrated in FIG. 1 includes 27 optical fiber bundles FB1 to FB27 corresponding to 27 modules MU1 to MU27 illustrated in FIG. 2, respectively.

The illumination unit ILU of the module MU18 includes a mirror 100 that reflects illumination light ILm traveling in the −Z direction from the emission end of the optical fiber bundle FB18, a mirror 102 that reflects the illumination light ILm from the mirror 100 in the −Z direction, an input lens system 104 serving as a collimator lens, an illuminance adjustment filter 106, an optical integrator 108 including a micro fly eye (MFE) lens, a field lens and so on, a condenser lens system 110, and a tilted mirror 112 that reflects the illumination light ILm from the condenser lens system 110 toward the DMD 10. The mirror 102, the input lens system 104, the optical integrator 108, the condenser lens system 110, and the tilted mirror 112 are arranged along an optical axis AXc parallel to the Z-axis.

The optical fiber bundle FB18 is formed of one optical fiber line or formed. by bundling a plurality of optical fiber lines. The illumination light Thin emitted from the emission end of the optical fiber bundle FB18 (each of the optical fiber lines) is set to a numerical aperture (NA, also referred to as a spread angle) such that it enters the input lens system 104 at a subsequent stage without being blocked. The position of the front focal point of the input lens system 104 is set to be the same as the position of the emission end of the optical fiber bundle FB18 in design. The position of the rear focal point of the input lens system 104 is set so that the illumination light ILm from a single or a plurality of point light sources formed at the emission end of the optical fiber bundle FB18 is superimposed on an incident surface side of an MFE lens 108A of the optical integrator 108. Therefore, the incident surface of the MFE lens 108A is Koehler-illuminated with the illumination light ILm from the emission end of the optical fiber bundle FB18. In an initial state, the geometric center point of the emission end of the optical fiber bundle FB18 in the XY plane is located on the optical axis AXc, and a principal ray (center line) of the illumination light ILm from the point source at the emission end of the optical fiber line is parallel to (or coaxial with) the optical axis AXc.

The illuminance of the illumination light ILm from the input lens system 104 is attenuated by the illuminance adjustment filter 106 at any value between 0% and 90%, and then the illumination light Ilm enters the condenser lens system 110 through the optical integrator 108 (the MFE lens 108A, the field lens, and so on). The MFE lens 108A is formed by two-dimensionally arranging a large number of rectangular microlenses each having several tens of μm square, and the entire shape of the MFE lens 108A is set to be substantially similar to the shape of the entire minor surface of the DMD 10 (aspect ratio is about 1:2) in the XY plane. The position of the front focal point of the condenser lens system 110 is set to be substantially the same as the position of the emission surface of the MFE lens 108A. Therefore, the illumination light from each of the point light sources formed on the emission sides of the many microlenses of the MFE lens 108A is converted into substantially parallel light beam by the condenser lens system 110, reflected by the tilted mirror 112, and then superimposed on the DMD 10 to form a uniform illuminance distribution. Since a surface light source in which a large number of point light sources (light condensing points) are two-dimensionally and densely arranged is generated on the emission surface of the MFE lens 108A, the MFE lens 108A functions as a member that forms a surface light source.

In the module MU18 illustrated in FIG. 4, an optical axis AXc parallel to the Z-axis passing through the condenser lens system 110 is bent by the tilted mirror 112 to reach the DMD10, and an optical axis between the tilted mirror 112 and the DMD 10 is defined as an optical axis AXb. In the present embodiment, a neutral plane including the center point of each of the micromirrors in the DMD10 is set in parallel with the XY plane. Therefore, an angle between a normal line (parallel to the Z-axis) of the neutral plane and the optical axis AXb is an incident angle θα of the illumination light ILm with respect to the DMD 10. The DMD 10 is attached to a lower side of a mount unit 10M fixed to a support column of the illumination unit ILU. In order to finely adjust the position and the orientation of the DMD 10, the mount unit 10M is provided with a fine movement stage that is a combination of a parallel link mechanism and an extendable piezoelectric element as disclosed in, for example, International Publication No. WO2006/120927.

### [Configuration of DMD]

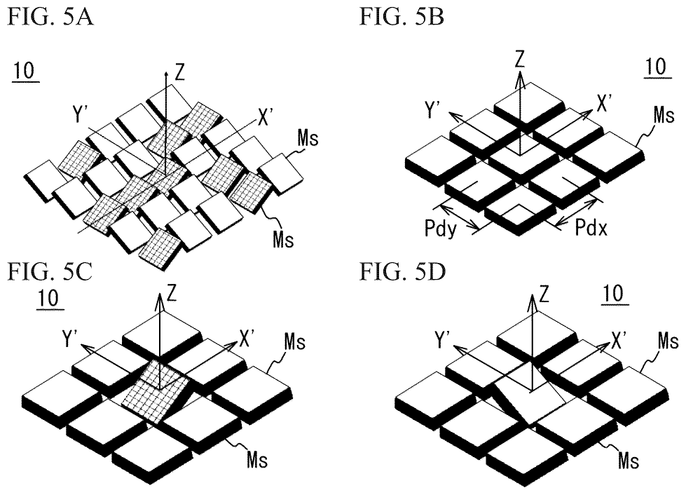

FIG. 5A schematically illustrates the DMD 10, FIG. 5B illustrates the DMD 10 when a power is off, FIG. 5C is a view for describing a mirror in an ON state, and FIG. 5D is a view for describing the mirror in an OFF state. In FIG. 5A to FIG. 5D, the mirrors in the ON state are represented by hatching.

The DMD10 has a plurality of micromirrors Ms of which reflection angles can be controlled to change. In the present embodiment, the DMD10 is of a roll-and-pitch driving type that switches between the ON and OFF states by tilting the micromirror Ms in a roll direction and a pitch direction.

As illustrated in FIG. 5B, when the power is off, the reflection surface of each micromirror Ms is set in parallel with an X′Y′ plane. An array pitch of the micromirrors Ms in the X′ direction is denoted by Pdx (μm), and an array pitch of the micromirrors Ms in the Y′ direction is denoted by Pdy (μm). In practice, Pdx=Pdy is set.

Each micromirror Ms becomes in the ON state by tilting around a Y′-axis. FIG. 5C illustrates a case where only the center micromirror Ms is in the ON state and the other micromirrors Ms are in the neutral state (a state other than the ON state and the OFF state). Each micromirror Ms becomes in the OFF state by tilting around an X′-axis. FIG. 5D illustrates a case where only the center micromirror Ms is in the OFF state and the other micromirrors Ms are in the neutral state. Although not illustrated for the sake of simplicity, the micromirrors Ms in the ON state are driven so as to be tilted at a predetermined angle from the X′Y′ plane so that the illumination light emitted to the micromirrors Ms in the ON state is reflected in the X-axis direction of the XZ plane. The micromirrors Ms in the OFF state are driven so as to be tilted at a predetermined angle from the X′Y′ plane so that the illumination light emitted to the micromirrors Ms in the OFF state is reflected in the Y-axis direction in the YZ plane. The DMD 10 switches the ON and OFF states of each micromirror Ms to generate an exposure pattern.

The illumination light reflected by the minor in the OFF state is absorbed by a light absorber (not illustrated).

Although the DMD10 has been described as an example of the spatial light modulator and thus as a reflective type that reflects the laser light, the spatial light modulator may be a transmissive type that transmits the laser light or a diffractive type that diffracts the laser light. The spatial light modulator can modulate the laser light spatially and temporally.

Returning to FIG. 4, the illumination light ILm emitted to the micromirrors Ms in the ON state out of the micromirrors Ms of the DMD10 is reflected in the X-axis direction in the XZ plane so as to be directed toward the projection unit PLU. On the other hand, the illumination light ILm emitted to the micromirrors Ms in the OFF state out of the micromirrors Ms of the DMD 10 is reflected in the Y-axis direction in the YZ plane so as not to be directed to the projection unit PLU.

A movable shutter 114 for blocking light reflected from the DMD 10 during a non-exposure period is removably provided in an optical path between the DMD 10 and the projection unit PLU. The movable shutter 114 is rotated to an angular position where it is retracted from the optical path during the exposure period as illustrated on the module MU19 side, and is rotated to an angular position where it is obliquely inserted into the optical path during the non-exposure period as illustrated on the module MU18 side. A reflection surface is formed on the DMD 10 side of the movable shutter 114, and light from the DMD 10 reflected by the reflection surface is irradiated to a light absorber 117. The light absorber 117 absorbs optical energy in an ultraviolet region (wavelengths equal to or shorter than 400 nm) without re-reflecting the optical energy, and converts the optical energy into heat energy. Therefore, the light absorber 117 is also provided with a heat dissipation mechanism (a heat dissipation fin or a cooling mechanism). Although not illustrated in FIG. 4, the light reflected by the micromirrors Ms of the DMD 10 in the OFF state during the exposure period is absorbed by a similar light absorber (not illustrated in FIG. 4) disposed in the Y-axis direction (direction peipendicular to a paper surface of FIG. 4) with respect to the optical path between the DMD 10 and the projection unit PLU.

### [Configuration of Projection Unit]

The projection unit PLU attached to the lower side of the optical surface plate 5 is configured as a both-side telecentric imaging projection lens system including a first lens system 116 and a second lens system 118 arranged along the optical axis AXa parallel to the Z-axis. The first lens system 116 and the second lens system 118 are configured to be translated by fine movement actuators in a direction along the Z-axis (optical axis AXa) with respect to support columns fixed to the lower side of the optical surface plate 5. A projection magnification Mp of the imaging projection lens system formed by the first lens system 116 and the second lens system 118 is determined by a relationship between an array pitch Pd of the micromirrors on the DMD 10 and a minimum line width (minimum pixel size) Pg of the pattern image projected in the projection region IAn (n=1 to 27) on the substrate P.

As an example, when the required minimum line width (minimum pixel size) Pg is 1 μm and each of the array pitches Pdx and Pdy of the micromirrors are 5.4 μm, the projection magnification Mp is set to approximately ⅙ in consideration of the tilt angle θk of the projection region IAn (DMD 10) in the XY plane described with reference to FIG. 3. The imaging projection lens system configured by the first and second lens systems 116 and 118 vertically-inverts/horizontally-inverts a reduced image of the entire mirror surface of the DMD10 and forms the resulting image on the projection region IA18 (IAn) on the substrate P.

The first lens system 116 of the projection unit PLU is finely movable in the direction of the optical axis AXa by an actuator in order to finely adjust the projection magnification Mp (about±several tens ppm), and the second lens system 118 is finely movable in the direction of the optical axis AXa by an actuator in order to adjust the focus at high speed. Further, in order to measure the positional change of the surface of the substrate P in the Z-axis direction with an accuracy of submicron or less, a plurality of focus sensors 120 of an oblique incident light type are provided on the lower side of the optical surface plate 5. The focus sensors 120 measure the overall positional change of the substrate P in the Z-axis direction, the positional change of a partial region on the substrate Pin the Z-axis direction corresponding to each of the projection regions IAn (n=1 to 27), or the partial tilt change of the substrate P. It is preferable that the focus sensors 120 measure focus positions before exposure in response to the scanning exposure of the substrate P. For this reason, since the scanning directions are the +X direction and the −X direction, it is desirable that the focus sensors 120 are disposed in front of and behind the projection unit PLU.

Since the illumination unit ILU and the projection unit PLU need to tilt the projection region IAn by the angle θk in the XY plane as described above with reference to FIG. 3, the DMD 10 and the illumination unit ILU (at least the optical path between the mirror 102 and the tilted mirror 112 along the optical axis AXc) in FIG. 4 are arranged so as to be tilted by the angle θk in the XY plane as a whole.

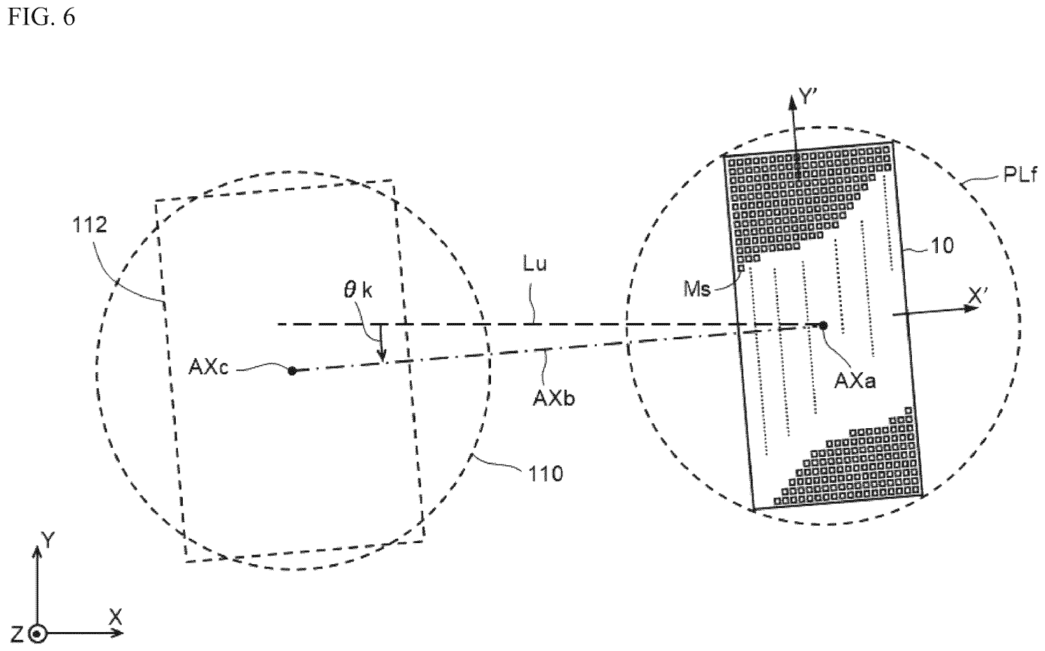

FIG. 6 schematically illustrates a state in which the DMD10 and the illumination unit ILU are tilted by the angle θk in the XY plane. In FIG. 6, an orthogonal coordinate system XYZ is the same as each of the coordinate systems XYZ of FIG. 1 to FIG. 4, and an arrangement coordinate system X′Y′ of the micromirrors Ms of the DMD 10 is the same as the coordinate system X′Y′ illustrated in FIG. 3. A circle encompassing the DMD 10 is an image field PLf on an object side of the projection unit PLU, and the optical axis AXa is positioned at the center of the circle. On the other hand, the optical axis AXb, which is the optical axis AXc that passes through the condenser lens system 110 of the illumination unit ILL and is bent by the tilted mirror 112, is arranged so as to be tilted by the angle θk from a line Lu parallel to the X-axis when viewed in the XY plane.

### [Imaging Optical Path by DMD]

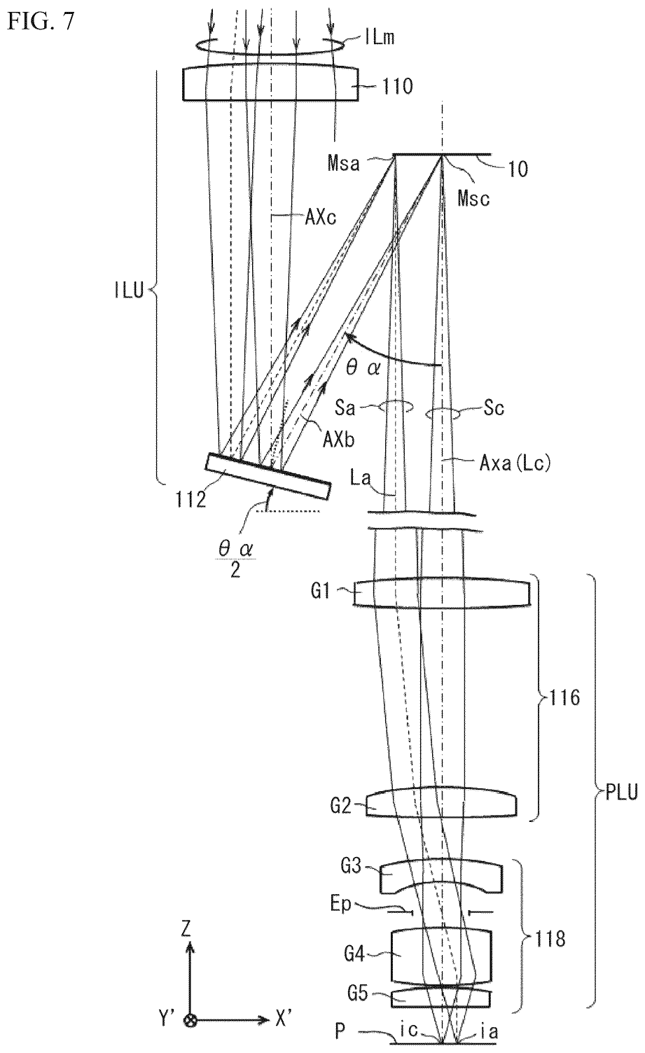

Next, the imaging state of the micromirrors Ms of the DMD 10 by the projection unit PLU (imaging projection lens system) will be described in detail with reference to FIG. 7. An orthogonal coordinate system X′Y′Z in FIG. 7 is the same as the coordinate system X′Y′Z illustrated in FIG. 3 and FIG. 6, and FIG. 7 illustrates an optical path from the condenser lens system 110 of the illumination unit ILU to the substrate P. The illumination light ILm from the condenser lens system 110 travels along the optical axis AXc, is totally reflected by the tilted mirror 112, and travels along the optical axis AXb to reach the mirror surface of the DMD 10. Here, the micromirror Ms positioned at the center of the DMD 10 is denoted by Msc, the micromirrors Ms surrounding the micromirror Msc are denoted by Msa, and the micromirrors and Msa are in the ON state.

If the tilt angle of the micromirror Ms in the ON state is, for example, 17.5° as a standard value with respect to the X′Y′ plane (XY plane), an incident angle θα of the illumination light ILm emitted onto the DMD 10 (an angle of the optical axis AXb from the optical axis AXa) is set to 35.0° in order to cause the principal rays of the reflected light Sc and the reflected light Sa from the micromirrors Msc and Msa to be parallel to the optical axis AXa of the projection unit PLU. Therefore, in this case, the reflection surface of the tilted mirror 112 is also tilted by 17.5° (=θα/2) with respect to the X′Y′ plane (XY plane). A principal ray Lc of the reflected light Sc from the micromirror Msc is coaxial with the optical axis AXa, a principal ray La of the reflected light Sa from the micromirror Msa is parallel to the optical axis AXa, and the reflected light Sc and the reflected light Sa enters the projection unit PLU with a predetermined numerical aperture (NA).

The reflected light Sc forms a reduced image ic of the micromirror Msc reduced at the projection magnification Mp of the projection unit PLU at the position of the optical axis AXa on the substrate P in a telecentric state. Similarly, the reflected light Sa forms a reduced image is of the micromirror Msa reduced at the projection magnification Mp of the projection unit PLU at a position on the substrate P away from the reduced image ic in the +X′ direction in the telecentric state. As an example, the first lens system 116 of the projecting unit PLU includes two lens groups G1 and G2, and the second lens system 118 includes three lens groups G3, G4, and G5. An exit pupil (also simply referred to as a pupil) Ep is set between the lens group G3 and the lens group G4 of the second lens system 118. A light-source image of the illumination light ILm (a set of a large number of point light sources formed on the emission surface side of the MFE lens 108A) is formed at the position of the pupil Ep, which configures the Koehler illumination. The pupil Ep is also called an aperture of the projection unit PLU, and the size (diameter) of the aperture is one factor that defines the resolution of the projection unit PLU.

The specular reflection light from the micromirror Ms in the ON state of DMD10 is set to pass through without being blocked by the maximum aperture diameter (diameter) of the pupil Ep, and the numerical aperture NAi on the image side (substrate P side) in the formula expressing resolution R, R=k1·(λ/NAi), is determined by the maximum aperture diameter of the pupil Ep and the rear side (image side) focal distance of the projection unit PLU (the lens groups G1 to G5 as the imaging projection lens system). Further, the numerical aperture NAo on the object plane (DMD 10) side of the projection unit PLU (lens groups G1 to G5) is expressed by the product of the projection magnification Mp and the numerical aperture NAi, and when the projection magnification Mp is ⅙, NAo=NAi/6 is satisfied.

In the configurations of the illumination unit ILU and the projection unit PLU illustrated in FIG. 7 and FIG. 4, the emission end of the optical fiber bundle FBn(n=1 to 27) connected to each module MUn (n=1 to 27) is set in an optically conjugate relationship with the emission end side of the MFE lens 108A of the optical integrator 108 by the input lens system 104, and the incident end side of the MFE lens 108A is set in an optically conjugate relationship with the center of the mirror surface (neutral surface) of the DMD 10 by the condenser lens system 110. The illumination light ILm illuminating the entire mirror surface of the DMD 10 thereby has a uniform illuminance distribution (for example, intensity irregularity within +1%) by the action of the optical integrator 108. The emission end side of the MFE lens 108A and the surface of the pupil Ep of the projection unit PLU are set in an optically conjugate relationship with each other by the condenser lens system 110 and the lens groups G1 to G3 of the projection unit PLU.

### [Configuration of Calibration Reference Unit CU]

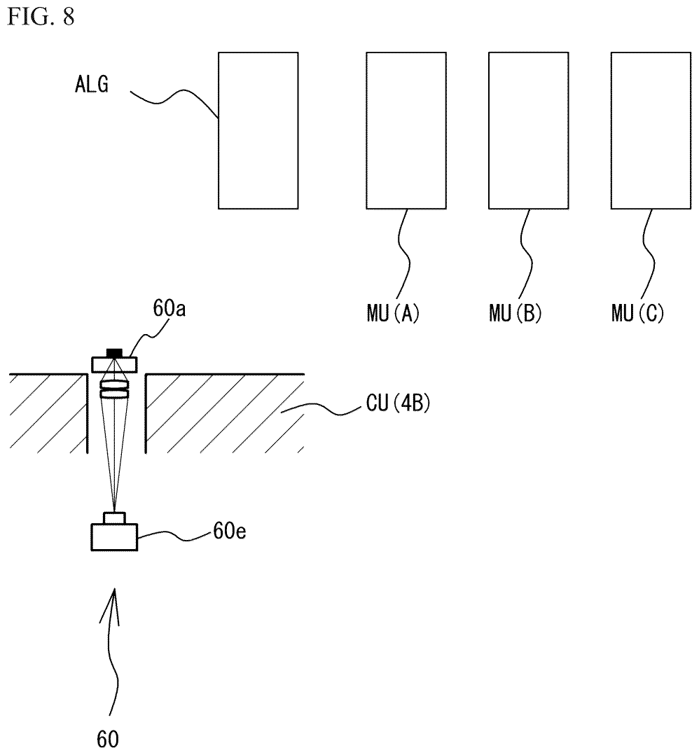

FIG. 8 illustrates a schematic configuration of an alignment device 60 provided in a calibration reference unit CU attached to the end portion of the substrate holder 4B of the exposure apparatus EX. The alignment device 60 includes a reference mark 60a, a two-dimensional imaging device 60e, and the like. The alignment device 60 is used for measurement and calibration of the positions of various modules, and is also used for calibration of the alignment system ALG.

The measurement of the position of each of the modules MU1 to MU27 is performed by projecting an image of a calibration pattern onto the reference mark 60a of the alignment device 60 by the projection unit PLU and measuring the relative position between the reference mark 60a and the image of the calibration pattern.

Further, the calibration of the alignment system ALG can be performed by measuring the reference mark 60a of the alignment device 60 by the alignment system ALG. That is, the position of the alignment system ALG can be obtained by measuring the reference mark 60a of the alignment device 60 by the alignment system ALG. Further, the relative position between the alignment system ALG and each of the modules MU1 to MU27 can be obtained using the reference mark 60a.

Further, the alignment system ALG can measure the position of the alignment mark on the substrate P placed on the substrate holder 4B, with reference to the reference mark 60a of the alignment device 60.

### [Configuration of Inspection Unit IU]

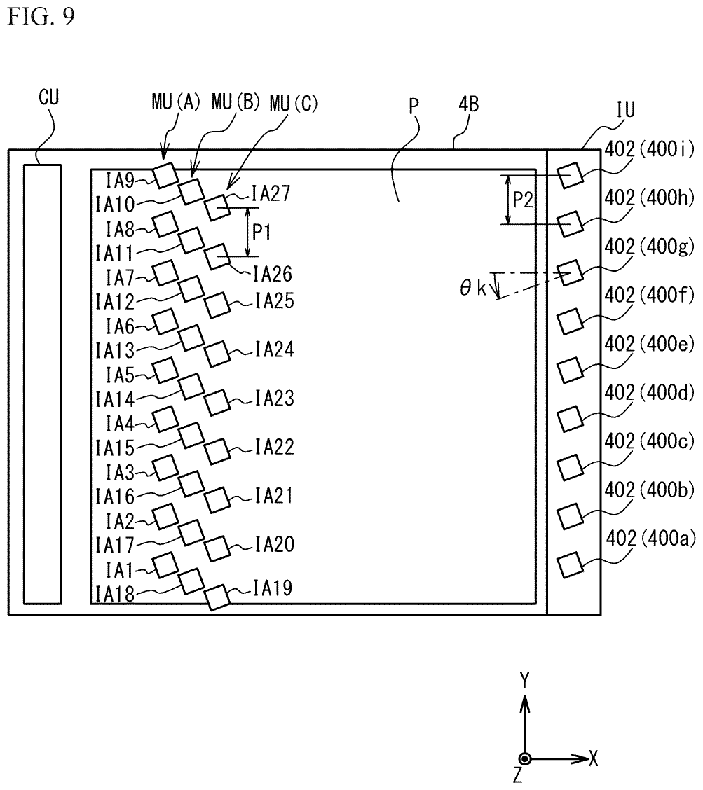

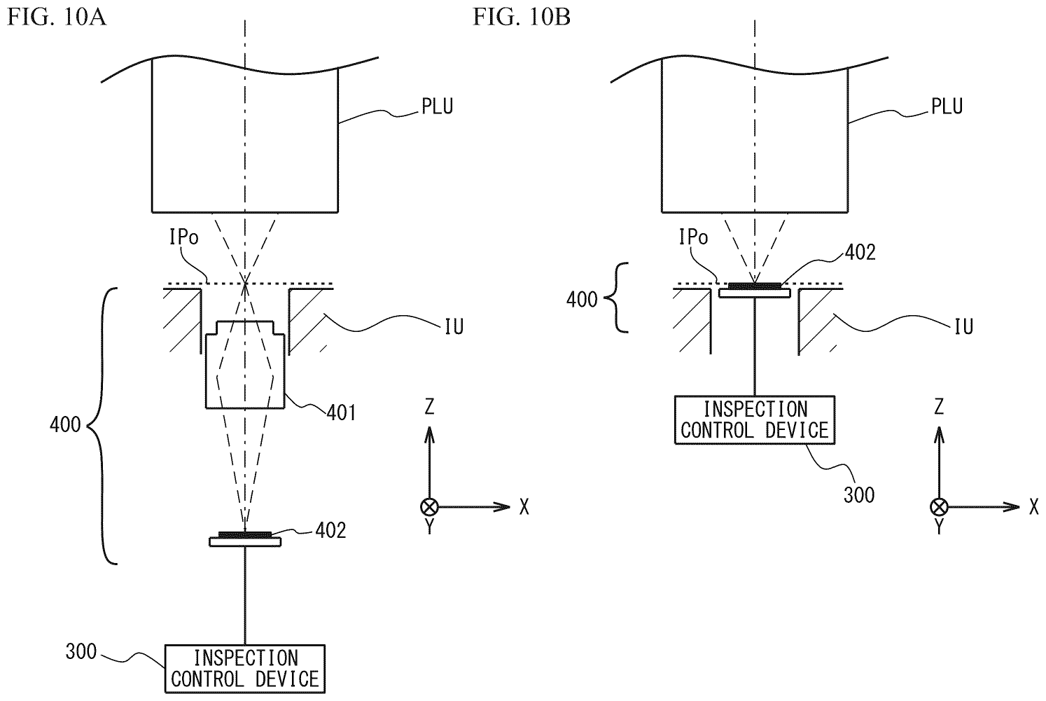

Next, the configuration of the inspection unit IU will be described. FIG. 9 illustrates the substrate holder 4B as viewed from the +Z direction. Further, FIG. 10A and FIG. 10B illustrate a schematic configuration of inspection devices 400a to 400i provided in the inspection unit IU provided at the end portion of the substrate holder 4B in the +X direction.

In the present embodiment, the inspection unit IU is provided on the opposite side of the substrate holder 4B from the calibration reference unit CU in the X-axis direction.

As illustrated in FIG. 9, the inspection devices 400a to 400i are arranged in the inspection unit IU in a direction (Y-axis direction) orthogonal to the scanning exposure direction (X-axis direction) of the substrate P. The inspection devices 400a to 400i are used to inspect whether the DMDs 10 of the modules MU1 to MU27 can generate pattern light in accordance with pattern data (drawing data). In particular, these devices are used to inspect whether the DMD 10 has a detective element (defective micromirror) that cannot be driven in accordance with the drawing data. The defective element is an element that cannot be driven in accordance with the drawing data because, for example, the micromirror Ms of the DMD 10 is stuck in the ON state or in the OFF state.

The inspection devices 400a to 400i are provided so as to correspond to the modules MU1 to MU9 included in the exposure module group MU(A), for example. That is, the inspection devices 400a to 400i are arranged such that a pitch P1 between the centers of the modules adjacent to each other in the Y-axis direction is equal to a pitch P2 between the centers of the inspection devices adjacent to each other in the Y-axis direction. In the following description, the inspection devices 400a to 400i are referred to as inspection devices 400, unless otherwise specified. The inspection devices 400 may be provided so as to correspond to the modules MU1 to MU27. That is, 27 inspection devices 400 may be arranged in the inspection unit IU. The number of the inspection devices 400 is not limited to the number illustrated in FIG. 9, and may be 8 or less or 10 or more.

As illustrated in FIG. 10A, the inspection device 400 includes an enlargement imaging system 401 that enlarges and forms the pattern image projected by the projection unit PLU and an imaging device 402 such as a CCD or a CMOS that images the enlarged image. In the inspection device 400, the object (micromirror Ms) at a predetermined position on the surface of the DMD 10, the image of the DMD 10 on an imaging plane IPo, and the image of the DMD 10 on the imaging device 402 are in a conjugate relationship with each other. Note that as illustrated in FIG. 10B, the inspection device 400 may include the imaging device 402 such as the CCD or the CMOS that directly images the pattern image projected by the projection unit PLU. In this case, the imaging device 402 is provided in the same plane as the substrate P or the substrate holder 4B.

In the present embodiment, as illustrated in FIG. 9, the imaging device 402 is tilted in the XY plane by the angle (θk: see FIG. 6) at which the DMD 10 is tilted in the XY plane. The imaging device 402 may not be tilted in the XY plane.

Here, when it is checked whether the DMD 10 has a defective element by using the imaging device, it is considered that pixels of the imaging device and elements (micromirrors) Ms of the DMD 10 are made to correspond to each other in a one to-one basis. In this case, the projected image is imaged in a state where the image of the pattern generated by the DMD 10 is projected on each pixel of the imaging device, and each pixel in the imaged image is checked by image processing or the like, whereby it is possible to easily check whether the corresponding element of the DMD 10 has a defect.

However, in an actual exposure apparatus, the image of the pattern generated by the DMD 10 is usually reduced by the projection unit PLU and projected onto the substrate P. For example, as described above, the image of the pattern generated by the DMD 10 is reduced to approximately ⅙ by the projection unit PLU. Therefore, when the pixels of the imaging device and the elements of the DMD 10 are made to correspond to each other in the one to-one basis, the enlargement imaging system 401 is required to enlarge the image of the pattern reduced and projected by the projection unit ITU by an inverse number of a reduction rate. Therefore, the enlargement imaging system 401 is increased in size, which leads to an increase in size of the inspection device 400. Further, the imaging device having at least the same number of pixels as the number of elements of the DMD 10 is used.

Therefore, in the present embodiment, a magnification ratio of the enlargement imaging system 401 is set so that each pixel IPX of the imaging device 402 includes the pattern images projected from a plurality of elements Ms of the DMD 10.

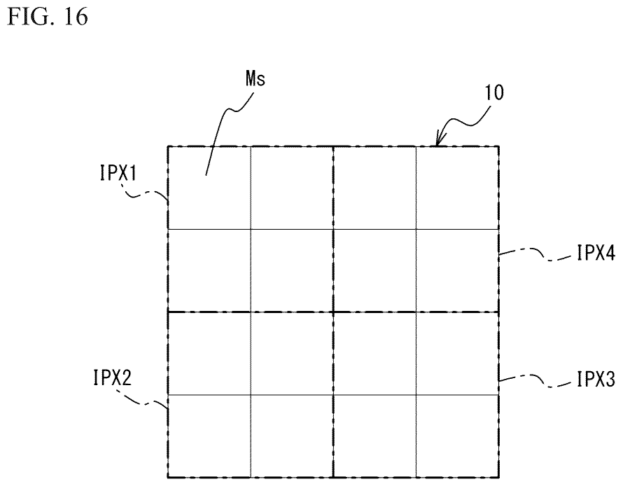

For example, as illustrated in FIG. 16, the plurality of elements (micromirrors) Ms (solid lines) of the DMD 10 are included in one pixel IPX1 (broken line) of the imaging device 402. The DMD 10 is divided into a plurality of regions (IPX1 to IPX4) so that 4(=2×2) elements Ms of the DMD 10 are included in one pixel IPX1 of the imaging device 402. At this time, the projected pattern images are enlarged so that the pattern images generated by the four elements Ms of the DMD 10 are projected onto the corresponding one pixel IPX1 of the imaging device 402. This can reduce the number of pixels required by the imaging device 402 (for example, it is ¼ times the number of pixels required by the imaging device 402 when one pixel of the pattern image corresponds to a pixel of the imaging device in the one-to-one basis), and thus the size of the imaging device 402 can be reduced. Further, since the magnification ratio of the enlargement imaging system 401 can be reduced, the size of the enlargement imaging system 401 can be reduced.

The number of elements of the DMD 10 included in each pixel of the imaging device 402 is determined by a relationship between the magnification ratio of the enlargement imaging system 401, the minimum pitch between pixels of the image of the pattern projected onto the substrate P, and the array pitch of the pixels of the imaging device 402.

### [Configuration of Inspection Control Device]

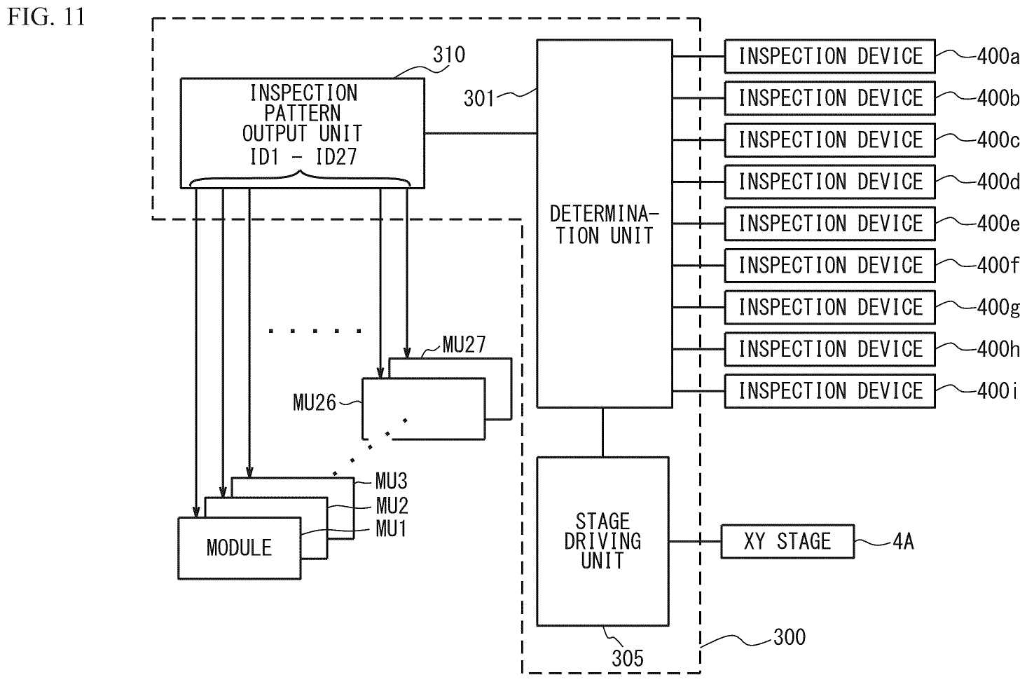

FIG. 11 is a functional block diagram of an inspection control device 300 that determine whether a detective element is present in the DMD 10 of each of the modules MU1 to MU27 and identifies a module of the DMD 10 having a defective element, based on the input from the inspection device 400.

As illustrated in FIG. 11, the inspection control device 300 includes an inspection pattern output unit 310, a determination unit 301, and a stage driving unit 305.

The inspection pattern output unit 310 outputs inspection pattern data ID1 to ID27 to the modules MU1 to MU27, respectively. The DMDs 10 of the modules MU1 to MU27 generate patterns based on the inspection pattern data ID1 to ID27, respectively.

The determination unit 301 determines whether the defective element is present in each of the DMDs10 of the modules MU1 MU27 based on the data input from the inspection devices 400a to 400i, and identifies the module of the DMD 10 having a defective element.

The stage driving unit 305 drives the XY stage 4A so that the modules MU1 to MU27 to be inspected are positioned above the inspection devices 400a to 400i.

### [Detection of Defective Element]

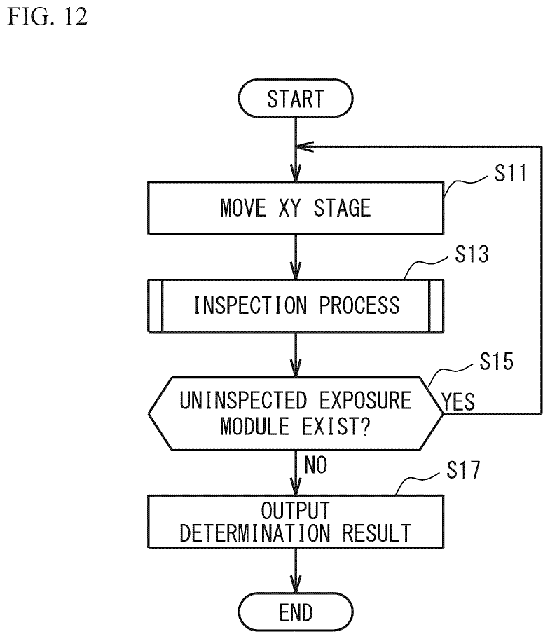

Next, processes executed by the inspection control device 300 will be described. FIG. 12 is a flowchart illustrating an example of the processes executed by the inspection control device 300.

In the processes of FIG. 12, first, the stage driving unit 305 drives the XY stage 4A to position the inspection devices 400a to 400i below the modules MU1 to MU9, respectively (step S11).

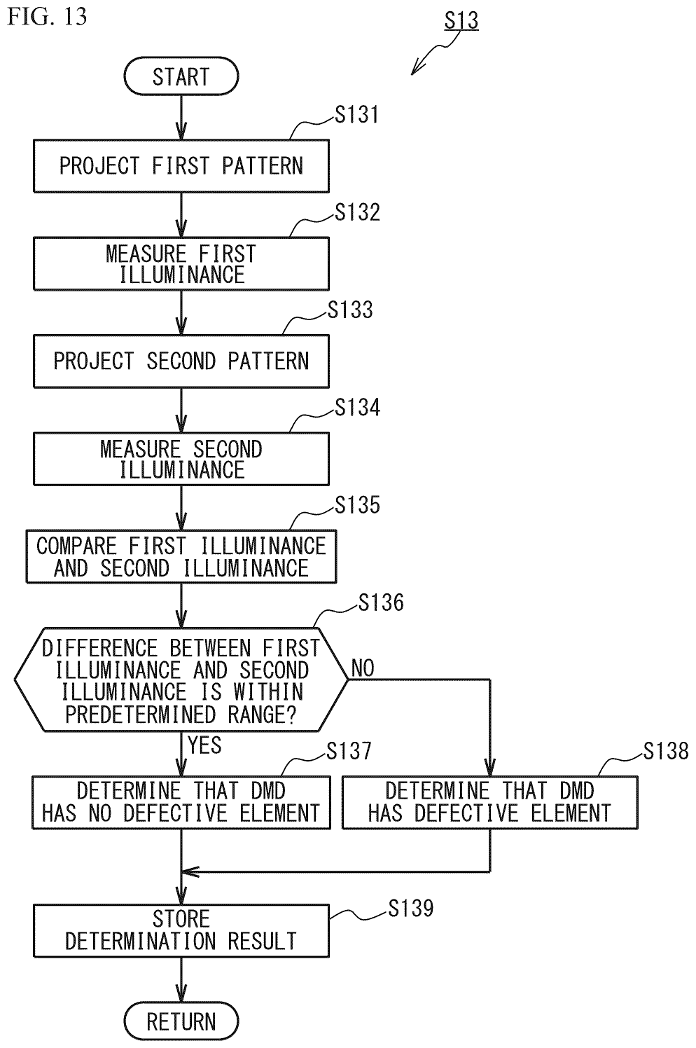

Next, the determination unit 301 performs an inspection process (step S13). FIG. 13 is a flowchart illustrating the details of the inspection process. The process of FIG. 13 is performed for each of the modules MU1 to MU9, and the module MU1 will be described below as an example.

In the process of FIG. 13, first, the inspection pattern output unit 310 outputs pattern data ID1 of a first inspection pattern to the module MU1, and the module MU1 projects an image of a pattern (referred to as a first pattern) generated by the DMD 10 based on the pattern data ID1 (step S131).

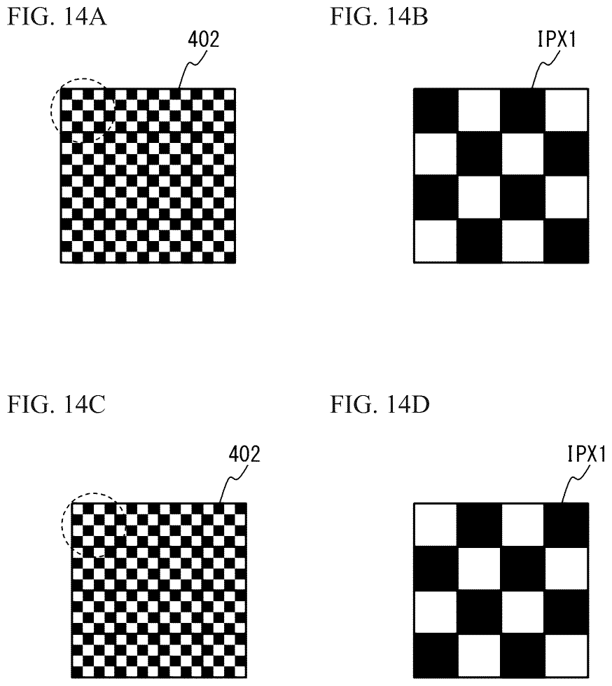

FIG. 14A illustrates an image of the first inspection pattern projected onto the imaging device 402 when the DMD 10 has no defective element, and FIG. 14B illustrates an image of the first inspection pattern projected on one pixel IPX1 of the imaging device 402 surrounded by a dotted line in FIG. 14A. The first inspection pattern is a zigzag pattern obtained by alternately switching the micromirrors Ms of the DMD 10 between the ON state and the OFF state. In FIG. 14A and FIG. 14B, black portions indicate the OFF state.

Next, the determination unit 301 measures an illuminance of an image of the projected first pattern for each pixel IPX of the imaging device 402 of the inspection device 400a (step S132). The illuminance acquired in step S132 is referred to as a first illuminance.

Next, the inspection pattern output unit 310 outputs the pattern data ID1 of the second inspection pattern to the module MU1, and the module MU1 projects an image of a pattern (referred to as a second pattern) generated by the DMD 10 based on the pattern data ID1 (step S133).

FIG. 14C illustrates an image of the second inspection pattern projected on the imaging device 402 when the DMD 10 has no defective element, and FIG. 14D illustrates an image of the second inspection pattern projected on one pixel IPX1 of the imaging device 402 surrounded by a dotted line in FIG. 14C. The second inspection pattern is a staggered pattern obtained by reversing the ON and OFF states of the micromirrors Ms of the DMD 10 from those of the first inspection pattern.

Then, the determination unit 301 measures an illuminance of an image of the projected second pattern for each pixel IPX of the imaging device 402 of the inspection device 400a (step S134). The illuminance acquired in step S134 is referred to as a second illuminance. Here, the first illuminance and the second illuminance include a brightness value and a gradation value of the imaging device.

Then, the determination unit 301 compares the first illuminance with the second illuminance (step S135). Here, the number of pixels in the ON state in the first inspection pattern is equal to the number of pixels in the ON state in the second inspection pattern, and the number of pixels in the OFF state in the first inspection pattern is also equal to the number of pixels in the OFF state in the second inspection pattern. Therefore, if the elements of the DMD 10 corresponding to each of the pixels IPX of the imaging device 402 do not include a defective element, a difference between the first illuminance and the second illuminance is substantially zero in each of the pixels IPX of the imaging device 402. Therefore, the determination unit 301 determines whether the difference between the first illuminance and the second illuminance is within a predetermined range (for example, within ±1%) for each pixel IPX of the imaging device 402 (step S136).

When the difference between the first illuminance and the second illuminance is within the predetermined range in all the pixels IPX of the imaging device 402 (step S136/YES), the determination unit 301 determines that the DMD 10 of the module MU1 does not have the defective element (step S137).

On the other hand, when the difference between the first illuminance and the second illuminance is not within the predetermined range in either of the pixels IPX of the imaging device 402 (step S136/NO), the determination unit 301 determines that the DMD 10 of the module MU1 has the defective element (step S138).

The determination unit 301 stores a determination result in a storage unit (not illustrated) such as a non-volatile memory (step S139).

The process of FIG. 13 is also performed on the other modules MU2 to MU9 included in the exposure module group MU(A), and the determination result of whether the DVD 10 of each of the modules MU1 to MU9 has the defective element is stored in the storage unit.

After the completion of step S139, the process returns to FIG. 12, and the determination unit 301 determines whether there is an exposure module that has not been inspected yet (step S15). For example, when the inspection of the modules MU1 to MU9 included in the exposure module group MU(A) is completed, the inspection of the exposure module groups MU(B) and MU(C) is not completed, and thus the determination in step S15 is YES.

When the determination in step S15 is YES, the process returns to step S11. Then, the stage driving unit 305 drives the XY stage 4A to position the inspection devices 400a to 400i below the modules MU18 to MU10 included in the exposure module group MU(B), respectively.

Then, the above-described inspection process is performed on the modules MU10 to MU18 (step S13).

When the inspection of the exposure module group MU(B) is completed, the exposure module group MU(C) has not been inspected yet (YES in step S15), and thus the process returns to step S11. The stage driving unit 305 drives the XY stage 4A to position the inspection devices 400a to 400i below the modules MU19 to MU27 included in the exposure module group MU(C), respectively (step 11). Then, the inspection of the exposure module group MU(C) is performed (step S13), and when the inspection of all the exposure module groups MU(A) to MU(C) is completed, the determination of step S15 becomes NO.

When the determination in step S15 is NO, the determination unit 301 outputs the determination results stored in the storage unit (step S17), and the process of FIG. 12 is terminated. At this time, the determination unit 301 may display the determination results on a display device such as a liquid crystal display, or may print the determination results by a printer. For example, the determination unit 301 outputs whether the DVD 10 has the defective element for each of the modules MU1 to MU 27.

When the DMD 10 having the defective element is present, the determination unit 301 may calculate an influence degree of the DMD 10 having the defective element on the exposure result of the pattern based on the recipe of the pattern to be exposed on the substrate P and the position of the DMD 10 having the defective element. In this case, the determination unit 301 may output the module including the DMD 10 having the defective element and the calculated influence degree. The determination unit 301 may output the influence degree and allow the operator to select whether to continue the exposure process. For example, the operator may be allowed to select whether to stop the exposure process, to perform the exposure process using the normal DMD 10 with no defective elements, or to continue the exposure process because the exposure result is less affected. Further, for example, the determination unit 301 may simulate the exposure result based on the recipe information of the pattern to be exposed on the substrate P and the position of the DMD 10 having the defective element, and output the simulation result. This allows the operator to more easily determine whether to continue the exposure process. Further, it is also possible to determine in advance a threshold value of the number of defective elements or the like or a threshold value of the number of defective elements that affect the scanning exposure pattern, and after the inspection, to select whether to continue the exposure process based on the obtained inspection results.

Further, when the difference between the first illuminance and the second illuminance is outside the predetermined range in the plurality of pixels IPX of the imaging device 402, the determination unit 301 may determine that a plurality of regions including the defective elements are present in the DMD 10 and output the determination result.

As described above in detail, according to the present embodiment, the exposure apparatus EX includes the DMD 10 that generates the pattern corresponding to drawing date, the illumination unit ILU that irradiates the DMD 10 with illumination light, the projecting unit PLU that reduces and projects the image of the pattern generated by the DMD 10 onto the substrate P placed on the substrate holder 4B, the inspection device 400 that detects the image of the projected pattern, and the determination unit 301 that determines whether the DMD 10 has the defective element based on the detection result of the inspection device 400. This makes it possible to inspect whether the DMD 10 has the defective element in the exposure apparatus EX.

In the present embodiment, the determination unit 301 determines whether the DMD 10 has the defective element based on the detection result of the image of the first pattern projected when the DMD 10 generates the first inspection pattern and the detection result of the image of the second pattern projected when the DMD 10 generates the second inspection pattern. The inspection device 400 detects the illuminance of the image of the first pattern and the illuminance of the image of the second pattern. The first inspection pattern is the staggered pattern obtained by alternately switching the elements of the DMD 10 between the ON state and the OFF state, and the second inspection pattern is the staggered pattern obtained by reversing the ON and OFF states of the first inspection pattern. This allows whether the DMD 10 has the defective element to be determined by comparing the illuminances without inspecting each element of the DMD 10.

In the present embodiment, as illustrated in FIG. 16, the inspection device 400 includes the imaging device 402 having a plurality of pixels IPX, and the enlargement imaging system 401 that enlarges the image of the projected pattern so that when the elements Ms of the DMD 10 are divided into a plurality of regions, the image of the pattern generated in each of the plurality of regions is projected onto the corresponding one of the pixels IPX1 to IPX4 of the imaging device 402. That is, each of the pixels IPX1 to IPX4 of the imaging device 402 receives light from the plurality of elements Ms of the DMD 10. This allows whether the DMD 10 has the defective element to be determined while reducing the size of the inspection device 400, as compared with the case where the defective element of the DMD 10 is detected using the imaging device 402 having pixels corresponding to the elements of the DMD 10 in the one-to-one basis.

In the present embodiment, the exposure apparatus EX includes a plurality of modules (for example, MU1 to MU9) arranged in the direction (Y-axis direction) orthogonal to the scanning exposure direction (X-axis direction) of the substrate P. Each of the plurality of modules includes the DMD 10, the illumination unit ILU, and the projection unit PLU. The plurality of inspection devices 400 (inspection devices 400a to 400i) are arranged in the Y-axis direction so as to correspond to the plurality of modules MU1 to MU9. Thus, the inspection time can be reduced, as compared with the case where the plurality of modules MU1 to MU9 are inspected by one inspection device 400.

In the above-described embodiment, the elements Ms of the DMD 10 corresponding to one pixel IPX of the imaging device 402 include 4×4=16 elements (FIG. 14) or 2×2=4 elements (FIG. 16), but this does not intend to suggest any limitation. The number of elements Ms of the DMD 10 corresponding to one pixel IPX of the imaging device 402 may be 5×5 or more, or may be 3×3. The number of elements Ms of the DMD 10 corresponding to one pixel IPX of the imaging device 402 may be not only an integer×integer relationship, but also 1.5×1.5.

In the above-described embodiment, the inspection devices 400a to 400i may also be used as the alignment device 60 provided in the calibration reference unit CU. That is, the imaging device 402 of the inspection device 400 may be used as the two-dimensional imaging device 60e of the alignment device 60.

In the above-described embodiment, although there is a possibility that the inspection device 400 may be increased in size, the projected pattern image may be imaged using the imaging device 402 having the pixels IPX corresponding to the elements Ms of the DMD 10 in the one-to-one basis, and it may be determined whether the DMD 10 has the defective element based on the imaged image. When the DID 10 has the defective element, the position of the defective element may be identified based on the imaged image.

In the above-described embodiment, instead of using the inspection device 400, a test pattern may be exposed on the substrate P, and the substrate P on which the test pattern has been exposed may be measured by a measurement device (microscope) to determine whether the DMD 10 has the defective element and identify the DMD 10 having the defective element. Alternatively, it is also possible to determine whether the DMD 10 has the defective element by irradiating the test pattern exposed on the substrate P with light and measuring diffracted light. Alternatively, a photochromic element may be arranged instead of the inspection device 400, the test pattern may be exposed on the photochromic element, and the exposure result may be observed and measured by the alignment system ALG to identify the defective element. When the pattern is exposed on the substrate on which the photochromic element is disposed, the measurement device may be a microscope of an inspection device used in an inspection process of the exposed substrate P.

In the above-mentioned embodiment, when the plurality of elements Ms of the DMD 10 are divided into the plurality of regions, the enlargement imaging system 401 is used so that the image of the pattern generated in each of the plurality of regions is projected onto the corresponding pixel IPX of the imaging device 402, but the enlargement imaging system 401 may be omitted as illustrated in FIG. 8B. In this case, the imaging device 402 is arranged on the substrate holder 4B so that its light receiving surface is located at substantially the same position as a best focus plane (best imaging plane) of the projection unit PLU in the Z-axis direction. In this case, the pattern image reduced by the projection unit PLU is projected onto the imaging device 402. Even in such a case, it is possible to determine whether the defective element is present in the DMD 10 by comparing, in the entire imaging device 402, the first illuminance of the image of the first pattern projected when the DMD 10 generates the first inspection pattern and the second illuminance of the image of the second pattern projected when the DMD 10 generates the second inspection pattern and determining whether the difference between the first illuminance and the second illuminance is within the predetermined range. In addition, since the enlargement imaging system 401 can be omitted, the inspection device 400 can be further reduced in size.

In the above-described embodiment, an illuminance sensor may be used instead of the imaging device 402.

The process of FIG. 13 of the above-described embodiment identifies whether the DMD 10 has the defective element, but does not identify the position of the defective element. The position of the defective element can be identified as follows.

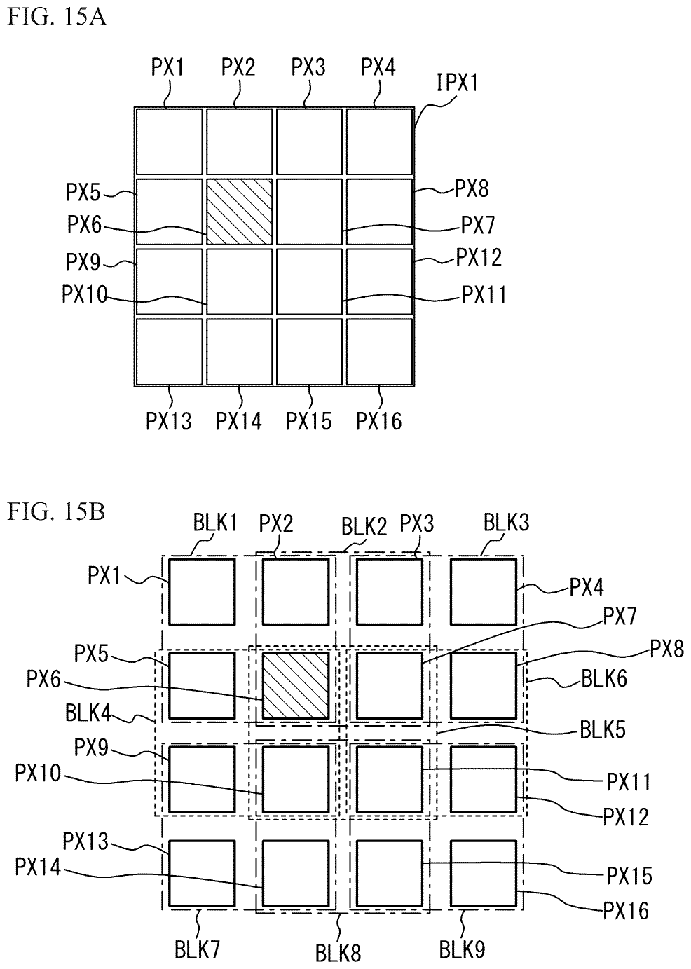

FIG. 15A illustrates the elements (Ms) PX1 to PX16 included in the region of the DMD 10 corresponding to one pixel IPX1 of the imaging device 402 (a first state). Here, for example, the element PX6 is assumed to be a defective element in the elements PX1 to PX16 illustrated in FIG. 15A. In this case, in the process described with reference to FIG. 13, it is possible to know that the defective element is present in the region of the DMD 10 corresponding to the pixel IPX1 of the imaging device 402, but it is not possible to identify which element is the defective element in the elements PX1 to PX16 included in the region.

In this case, for example, the defective element can be identified by repeating the comparison between the first illuminance of the image of the first pattern projected when the first inspection pattern is generated by some of the 4×4 elements PX1 to PX16 in the region of the DMD 10 corresponding to the pixel IPX1 and the second illuminance of the image of the second pattern projected when the second inspection pattern is generated by said some of 4×4 elements PX1 to PX16.

A method of identifying the defective element will be described in more detail. For example, blocks each including a plurality of elements adjacent to each other in the X-axis direction and the Y-axis direction are defined in the elements PX1 to PX16. The elements included in each block are included in one pixel IPX1 used in the first state (a second state). The number of elements included in each block is smaller than the number of elements included in the pixel IPX1. This is achieved by changing the magnification ratio of the enlargement imaging system 401 to change the elements included in one pixel IPX1 between the first state and the second state at the same pixel.

For example, as illustrated in FIG. 15B, a block BLK1 including the elements PX1, PX2, PX5 and PX6, a block BLK2 including the elements PX2, PX3, PX6 and PX 7, and a block BLK3 including the elements PX3, PX4, PX7 and PX8 are defined. Also, a block BLK4 including the elements PXS, PX6, PX9 and PX10, a block BLK5 including the elements PX6, PX7, PM10 and PX11, and a block BLK6 including the elements PX7, PX8, PX11 and PX12 are defined. Further, a block BLK7 including the elements PX9, PX10, PX13 and PX14, a block BLK8 including the elements PX10, PX11, PX14 and PX15, and a block BLK9 including the elements PX11, PX12, PX15 and PX16 are defined. In FIG. 15A and 15B, the elements are drawn apart from each other to make the drawing easier to view.

Next, the presence or absence of defective elements is determined by comparing the first illuminance of the image of the first pattern projected when the first inspection pattern is generated by the elements included in each of the blocks BLK1 to BLK9 and the second illumination of the image of the second pattern projected when the second inspection pattern is generated by the elements included in each of the blocks BLK1 to BLK9. In the example of FIG. 15B, since the defective element PX6 is included in the block BLK1, the block BLK2, the block BLK4, and the block BLK5, it is determined that the defective element is present in the block BLK1, the block BLK2, the block BLK4, and the block BLK5. In this case, since an element common to the block BLK1, the block BLK2, the block BLK4, and the block BLK5 is the element PX6, it can be determined that the element PX6 is the defective element.

In this way, the plurality of elements included in the region of the DMD 10 corresponding to one pixel of the imaging device 402 are divided into the plurality of blocks so that a common element is included in blocks adjacent in the X-axis direction and the Y-axis direction, and the presence or absence of the defective element in each block is determined, so that the detective element can be identified even when the pixels of the imaging device and the elements of the DMD 10 do not correspond to each other in the one-to-one basis.

When the position of the defective element included in the DMD 10 is also identified, the determination unit 301 may determine and output the influence of the defective element on the pattern exposure result in consideration of the position of the defective element.

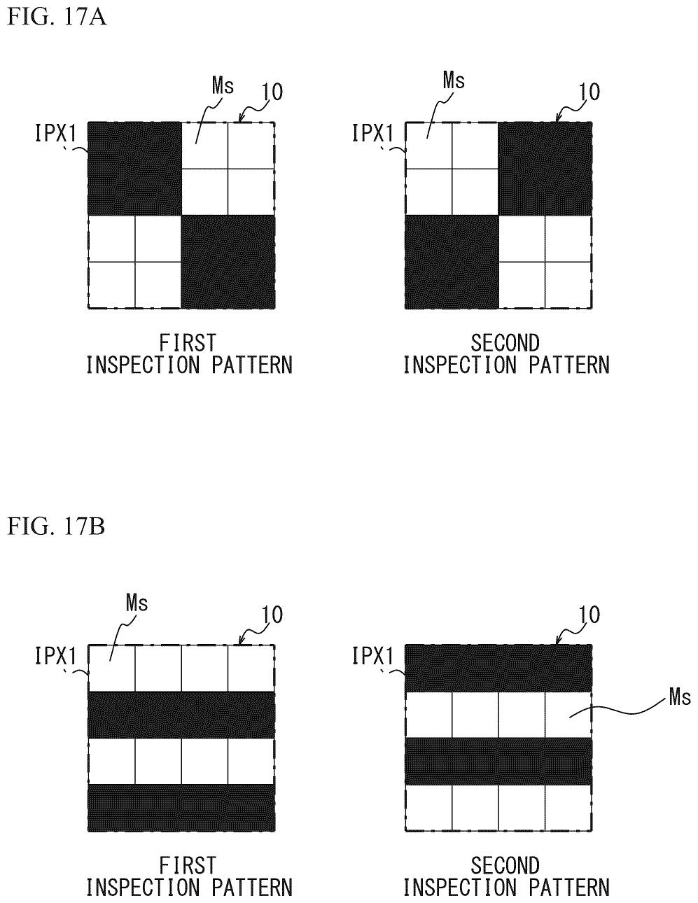

The embodiments described above are examples of preferred embodiments of the present invention. However, the present invention is not limited thereto, and various modifications can be made without departing from the scope of the present invention. Further, in order to identify the defective element of the DMD 10, the alignment device 60 may directly observe the elements Ms of the DMD 10 by switching a portion considered as the defective element between ON and OFF In this case, it is desirable to perform observation at an optical magnification at which the pixels of the alignment device 60 are made larger than the elements Ms of the DMD 10. In the present embodiment, the staggered pattern (i.e., hound's-tooth pattern) in which the ON/OFF of the adjacent elements Ms are opposite is illustrated as an example. In addition, when 16 (=4×4) elements of the DMD 10 are included in one pixel IPX1 of the imaging device 402 as illustrated in FIG. 17A, a staggered pattern in which four elements Ms are collectively turned on or off may be used. The inspection pattern is not limited to the staggered pattern, and when 16 (=4×4) elements of the DVD 10 are included in one pixel IPX1 of the imaging device 402 as illustrated in FIG. 17B, the first inspection pattern and the second inspection pattern may be patterns other than the staggered pattern. Although the pattern is not the staggered pattern, each of the 16 elements in the pixel IPX1 becomes the exposure ON state or exposure OFF state once by the first inspection pattern or the second inspection pattern. By using such a pattern, the defective element can be identified. The inspection pattern of the present invention is not limited to this, and can be designed as appropriate without departing from the scope of the present invention.

Further, the detective element may be identified as follows. The first inspection pattern is set to a pattern for turning on one specific element included in the pixel IPX, the second inspection pattern is set to a pattern for turning off all elements included in the pixel IPX, and a difference between an inspection result of the first inspection pattern and an inspection result of the second inspection pattern is measured. By performing this operation on all the elements included in the pixel IPX, the presence or absence of the defective element can be identified.

The following additional remarks are disclosed in relation to the above description of the embodiment.

(Additional remark 1) An exposure apparatus including: a spatial light modulator configured to generate a pattern according to drawing data; an illumination unit configured to irradiate the spatial light modulator with illumination light; a projection unit configured to reduce and project an image of the pattern generated by the spatial light modulator onto a substrate placed on a substrate holder; a detection unit configured to detect the image of the pattern that has been projected; and a determination unit configured to determine whether the spatial light modulator has a defective element based on a detection result of the detection unit.

(Additional remark 2) The exposure apparatus according to additional remark 1, wherein the determination unit determines whether the spatial light modulator has a defective element based on a detection result of a first pattern image projected when the spatial light modulator generates a first inspection pattern and a detection result of a second pattern image projected when the spatial light modulator generates a second inspection pattern.

(Additional remark 3) The exposure apparatus according to additional remark 2, wherein the detection unit detects an illuminance of the first pattern image and an illuminance of the second pattern image.

(Additional remark 4) The exposure apparatus according to additional remark 2 or 3, wherein the first inspection pattern is a staggered pattern obtained by alternately switching elements of the spatial light modulator between an ON state and an OFF state, and the second inspection pattern is a staggered pattern obtained by reversing the ON state and the OFF state of the first inspection pattern.

(Additional remark 5) The exposure apparatus according to any one of additional remarks 1 to 4, further comprising a plurality of modules each including the spatial light modulator, the illumination unit, and the projection unit, the plurality of modules being arranged in a direction orthogonal to a scanning exposure direction of the substrate, wherein the detection unit is provided in plural, and the plural detection units are arranged in the direction orthogonal to the scanning exposure direction so as to correspond to the plurality of modules.

(Additional remark 6) The exposure apparatus according to any one of additional remarks 1 to 5, wherein the detection unit is installed on the substrate holder.

(Additional remark 7) The exposure apparatus according to any one of additional remarks 1 to 6, wherein the detection unit includes an imaging device having a plurality of pixels, and an enlargement imaging system that enlarges the image of the pattern that has been projected so that when the plurality of elements of the spatial li modulator are divided into a plurality of regions, the image of the pattern generated in each of the plurality of regions is projected onto a corresponding pixel of the imaging device.

(Additional remark 8) The exposure apparatus according to any one of additional remarks 1 to 6, wherein the detection unit includes an imaging device on which the image of the pattern is projected without being enlarged.

(Additional remark 9) The exposure apparatus according to additional remark 7 or 8, wherein the imaging device is used to measure a position of a module including the spatial light modulator, the illumination unit, and the projection unit.

(Additional remark 10) The exposure apparatus according to any one of additional remarks 7 to 9, wherein the detection unit includes an illuminance sensor configured to measure an illuminance of the image of the pattern that has been projected.

(Additional remark 11) An inspection method for inspecting a spatial light modulator in an exposure apparatus, the exposure apparatus including the spatial light modulator configured to generate a pattern in accordance with drawing data; an illumination unit configured to irradiate the spatial light modulator with illumination light; and a projection unit that reduces and projects an image of the pattern generated by the spatial light modulator onto a substrate placed on a substrate holder, the inspection method including: detecting the image of the pattern that has been projected; and determining whether the spatial light modulator has a defective element based on a detection result of the image of the pattern.

(Additional remark 12) An inspection method for inspecting a spatial light modulator in an exposure apparatus, the exposure apparatus including the spatial light modulator configured to generate a pattern in accordance with drawing data; an illumination unit configured to irradiate the spatial light modulator with illumination light; and a projection unit that reduces and projects an image of the pattern generated by the spatial light modulator onto a substrate placed on a substrate holder, the inspection method including: exposing the image of the pattern generated by the spatial light modulator onto the substrate; and determining whether the spatial light modulator has a defective element by measuring the substrate to which the image of the pattern is exposed using a measurement device.

(Additional remark 13) An inspection method for inspecting a spatial light modulator in an exposure apparatus, the exposure apparatus including the spatial light modulator configured to generate a pattern in accordance with drawing data; an illumination unit configured to irradiate the spatial light modulator with illumination light; and a projection unit that reduces and projects an image of the pattern generated by the spatial light modulator onto a substrate placed on a substrate holder, the inspection method including: exposing the image of the pattern generated by the spatial light modulator onto a photochromic element; and determining whether the spatial light modulator has a detective element by measuring the photochromic element to which the image of the pattern is exposed by using a measurement device.

1. An exposure apparatus comprising:
a spatial light modulator including a plurality of elements driven in accordance with drawing data;
a data output unit configured to output the drawing data to the spatial light modulator;
an illumination optical system configured to irradiate the spatial light modulator with illumination light;
a first movable body configured to hold an object;
a projection optical system configured to project an image of the pattern light generated by the spatial light modulator onto the object;
a detection unit configured to detect the image of the pattern light; and
a determination unit configured to determine whether the spatial light modulator is capable of generating pattern light in accordance with the drawing data, based on a detection result of the detection unit.

2. The exposure apparatus according to claim 1, wherein the determination unit is configured to determine whether the spatial light modulator includes a defective element uncapable of being driven in accordance with the drawing data, based on the detection result.

3. The exposure apparatus according to claim 2,
wherein the detection unit is configured to detect an image of a first pattern generated by at least part of the plurality of elements of the spatial light modulator to which a first inspection pattern data is output to and an image of a second pattern generated by the at least part of the plurality of elements of the spatial light modulator to which a second inspection pattern data is output, and
wherein the detection result includes a detection result of the image of the first pattern and a detection result of the image of the second pattern.

4. The exposure apparatus according to claim 3, wherein the detection unit is configured to detect an illuminance of the image of the first pattern and an illuminance of the image of the second pattern.

5. The exposure apparatus according to claim 3,
wherein the first inspection pattern data makes the spatial light modulator, in which each of the plurality of elements is no defective element, generate a first inspection pattern where the at least part of the plurality of elements alternately switches between an ON state and an OFF state, and
wherein the second inspection pattern data makes the spatial light modulator, in which each of the plurality of elements is no defective element, generate a second inspection pattern where the ON state and the OFF state of the first inspection pattern is reversed.

6. The exposure apparatus according to claim 5, wherein the first inspection pattern is a staggered pattern, and the second inspection pattern is a staggered pattern.

7. The exposure apparatus according to claim 1,
a plurality of modules each including the spatial light modulator, the illumination optical system, and the projection optical system, the plurality of modules being arranged in a direction orthogonal to a scanning exposure direction of the object;
wherein the detection unit is arranged in plural in the direction orthogonal to the scanning exposure direction so as to correspond to the plurality of modules.

8. The exposure apparatus according to claim 1, wherein the detection unit translates with the first movable body.

9. The exposure apparatus according to claim 8, wherein the detection unit is provided on the first movable body.

10. The exposure apparatus according to claim 1, wherein the detection unit includes an imaging device including a plurality of pixels and taking the image of the pattern light projected from the projection optical system.

11. The exposure apparatus according to claim 10, wherein a light receiving surface of the imaging device is provided in substantially a same plane as the object.

12. The exposure apparatus according to claim 10,
wherein the detection unit includes a detection optical system above the imaging device, and
wherein the detection optical system forms an enlarged image obtained by enlarging the image formed on substantially the same plane as the object, on the imaging device.

13. The exposure apparatus according to claim 12,
wherein the detection optical system forms the image of the pattern light on the imaging device so that two or more of the elements are included in one pixel of the imaging device, and
wherein the determination unit is configured to determine whether pattern light in accordance with the drawing data can be generated based on a detection result of the elements included in the one pixel.

14. The exposure apparatus according to claim 13,
wherein the detection optical system forms the image of the pattern light on the imaging device in a first state in which the pattern light is formed on the imaging device so that the two or more of the elements are included in the one pixel of the imaging device and a second state in which a number of the elements included in the one pixel is smaller than that in the first state, and
wherein the determination unit is configured to determine whether the spatial light modulator includes a defective element uncapable of being driven in accordance with the drawing data, based on a first detection result measured in the first state and a second detection result measured in the second state.

15. The exposure apparatus according to claim 14, comprising:
a module unit that includes the spatial light modulator, the illumination optical system, and the projection optical system,
wherein the detection unit performs position measurement of the module unit in addition to detection of the defective element.

16. The exposure apparatus according to claim 1, wherein the detection unit includes an illuminance sensor configured to measure an illuminance of the image of the pattern light projected from the projection optical system.

17. An inspection method for inspecting a spatial light modulator of an exposure apparatus that includes the spatial light modulator including a plurality of elements that generate pattern light in accordance with drawing data, an illumination optical system configured to irradiate the spatial light modulator with illumination light, and a projection optical system configured to project an image of the pattern light generated by the spatial light modulator onto an object placed on a first movable body, the inspection method comprising:
detecting the image of the pattern light projected from the projection optical system; and
determining whether the spatial light modulator includes a defective element uncapable of being driven in accordance with the drawing data, based on a detection result of the image of the pattern light.

18. The inspection method according to claim 17, further comprising:
exposing the image onto the object; and
determining whether the spatial light modulator includes a defective element uncapable of being driven in accordance with the drawing data by measuring the exposed object by a measurement device.

19. The inspection method according to claim 17, further comprising:
exposing the image of the patterned light generated by the spatial light modulator onto a photochromic element; and
determining whether the spatial light modulator includes a defective element uncapable of being driven in accordance with the drawing data by measuring the exposed photochromic element by a measurement device.

20. An exposure apparatus comprising:
a spatial light modulator including a plurality of elements driven in accordance with drawing data:
an illumination optical system configured to irradiate the spatial light modulator with illumination light;
a first movable body configured to hold the object;
a projection optical system configured to project an image of the pattern light generated by the spatial light modulator onto the object; and
a measurement unit configured to obtain a measurement result of the image of the pattern light,
wherein the measurement unit is configured to determine whether the spatial light modulator includes a defective element uncapable of being driven in accordance with the drawing data, based on the measurement result.

21. The exposure apparatus according to claim 20,
wherein the first movable body is configured to hold a photochromic element;
wherein the projection optical system is configured to project the image of the pattern light generated by the spatial light modulator onto the photochromic element; and
wherein the measurement unit is configured to obtain a measurement result of the projected photochromic element;
wherein the measurement unit is configured to determine whether the spatial light modulator includes a defective element uncapable of being driven in accordance with the drawing data, based on the measurement result.

22. The exposure apparatus according to claim 1,
wherein the first movable body is configured to move relative to the projection optical system in a scanning exposure direction,
wherein the detection unit is provided on the first movable body and located between a region of the first movable body and an edge of the first movable body in the scanning exposure direction, the region holding the object, and
wherein the first movable body is configured to move between a position where the projection optical system projects the image of the pattern light onto the object and a position where the detection unit detects the image of the pattern light.
